(19) United States
(12) Patent Application Publication
(10) Pub. No.: US 2004/0173903 A1
(43) Pub. Date: Sep. 9, 2004

(54) Thin type ball grid array package

(75) Inventors: Chaur-Chin Yang, Tainan (TW); Sung-Fei Wang, Kaohsiung (TW)

Correspondence Address: BRUCE H. TROXELL, SUITE 1404, 5205 LEESBURG PIKE, FALLS CHURCH, VA, 22041, US

(73) Assignee: Advanced Semiconductor Engineering Inc.

(21) Appl. No.: 10/733,365

(22) Filed: Dec. 12, 2003

(30) Foreign Application Priority Data
Mar. 6, 2003 (TW) 092203564

(51) Int. Cl. H01L 23/48

(52) U.S. Cl. 257/738

(57) ABSTRACT

A thin type ball grid array package is provided. A composite substrate for the package is consisted of a wiring board and a dummy die. The wiring board has an opening through upper and lower surfaces thereof. The dummy chip is attached to one surface of the wiring board, and covers the opening to form a chip cavity for accommodating an integrated circuit chip. The wiring board has a step with a plurality of connecting pads in the opening. The integrated circuit chip is attached to the dummy die and electrically connected to the connecting pads of the wiring board. A package body is formed in the chip cavity.

### FIELD OF THE INVENTION

The present invention is relating to a ball grid array package, particularly to a thin type ball grid array package with a composite substrate including a dummy die.

### BACKGROUND OF THE INVENTION

According to a conventional thin type ball grid array package (thin type BGA package), an integrated circuit chip is accommodated inside the cavity of a BGA package substrate for reducing the total height of the package

A thin type BGA package had been disclosed in U.S. Pat. No. 6,486,537 entitled “semiconductor package with warpage resistant substrate”. The thin type BGA package comprises a BGA package substrate with a through hole and a chip positioned in the through hole by a hardened encapsulate material. During molding process, back surface of the chip is attached to a temporary adhesive inside a mold and the back surface of the chip is exposed to the encapsulating material. Since only the back surface of the chip is used for thermal dissipation, the thin type BGA package not only has poor thermal dissipation, but also cannot supply enough protection to the chip due to the exposed back surface of the chip, resulting in easily damaging the chip and poor reliability.

### SUMMARY

A primary objective of the present invention is to provide a thin type BGA package having a composite substrate. A dummy die is attached to a wiring board with an opening to form a composite substrate with a chip cavity. The dummy die covers the opening for mounting an integrated circuit chip in the chip cavity. The wiring board has a step formed in the opening for electrically connecting the chip. The chip is attached to the dummy die of the composite substrate so that the thin type BGA package has a larger thermal dissipating surface and a better protection for the chip. Moreover, CTEs (coefficient of thermal expansion) of the chip and the dummy die are the same, so the interface between the chip and the dummy die will not have residual thermal stress, therefore, delamination can be eliminated.

A secondary objective of the present invention is to provide a thin type BGA package. A dummy die is attached to a wiring board with an opening to form a composite substrate. The dummy die covers the opening so as to form a chip cavity for accommodating an integrated circuit chip which has the advantage to achieve a smaller total package height.

According to the thin type BGA package of the present invention, the package comprises a composite substrate, an integrated circuit chip, a package body and a plurality of solder balls. The composite substrate includes a wiring board and a dummy die. The wiring board has an upper surface, a lower surface and an opening. Ball pads are formed on the upper surface or the lower surface of the wiring board. A step with a plurality of connecting pads is formed in the opening. The connecting pads on the step are electrically connected with the chip by bonding wires to reduce the loop height. The dummy die is attached to the lower surface of the wiring board and covers the opening to form a chip cavity of the thin type BGA package which has the advantage to form the package body by dispensing method. The back surface of chip is attached to the dummy chip inside the chip cavity. A larger thermal dissipating surface is created on the exposed surface of the dummy chip. Moreover, there is no thermal stress between the interface of the chip and the dummy die due to the perfect matching of CTEs (coefficient of thermal expansion), so that the possibility of delamination at the interface can be effectively reduced. Therefore, excellent thermal dissipation, excellent protection of the die and excellent stress releasing of the chip can be achieved.

### DESCRIPTION OF THE DRAWINGS

FIG. 1 is a cross-sectional view illustrating a thin type BGA package of the present invention.

FIG. 2A to FIG. 2D is cross-sectional views illustrating manufacturing process of a thin type BGA package of the present invention.

FIG. 3 is a cross-sectional view illustrating another thin type BGA package of the present invention.

### DETAILED DESCRIPTION OF THE PRESENT INVENTION

Referring to the drawings attached, the present invention will be described by means of the embodiment below.

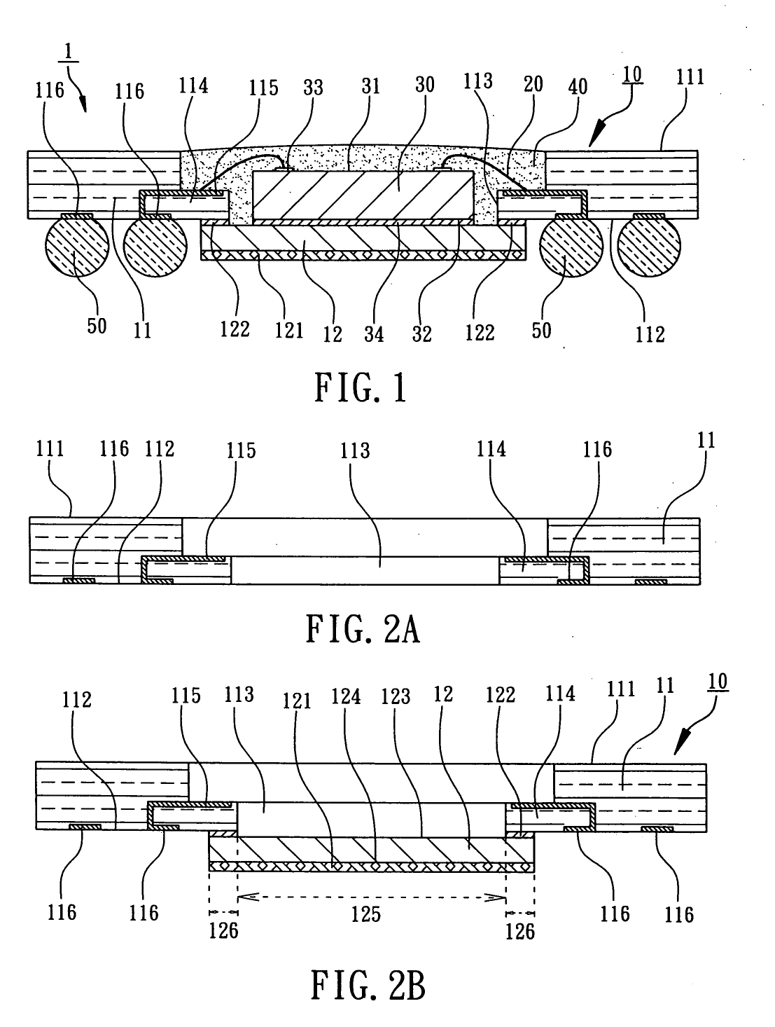

According to a first embodiment of the present invention showed in FIG. 1, a thin type BGA package 1 comprises a composite substrate 10, an integrated circuit chip 30, a package body 40 and a plurality of solder balls 50. The composite substrate 10 is consisted of a wiring board 11 with an opening 113, and a dummy die 12.

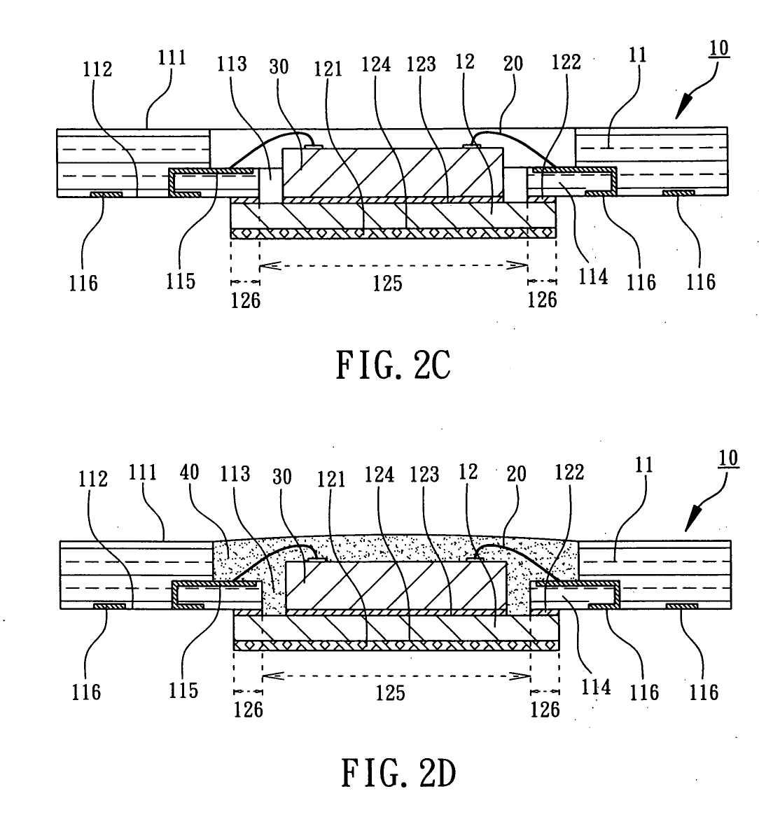

As shown FIG. 1 and 2A, the wiring board 11 is a printed circuit board (PCB) made of glass fiber reinforced resin, such as FR-4, FR-5, BT resin, etc. The wiring board 11 has multiple layers of metal traces, preferably it is made by a build-up processes. The wiring board 11 has an upper surface 111, a lower surface 112 and an opening 113 passing through the upper surface 111 and the lower surface 112. The opening 113 is larger than the integrated circuit chip 30 in dimension for accommodating the integrated circuit chip 30. In the embodiment the wiring board 11 has a step 114 in the opening 113. There is a plurality of connecting pads 115 formed on the step 114 between the upper surface 111 and the lower surface 112 for the connection of bonding wires. Furthermore, a plurality of ball pads 116 for the placement of solder balls 50 are formed on the lower surface 112 and electrically connected with the connecting pads 115 through the layers of traces. Alternatively the ball pads 116 may be formed on the upper surface 111. The dummy die 12 is attached to the lower surface 112 of the wiring board 11 by a thermosetting compound 122, such as epoxy compound, and covers the opening 113. The dummy die 12 is larger than the opening 113 but is smaller than the wiring board 11 in dimension. The dummy die 12 has a first surface 123 and an opposing second surface 124. The first surface 123 includes a central region 125 and a peripheral region 126 surrounding the central region 125. The peripheral region 126 of the dummy die 12 is attached to the lower surface 112 of the wiring board 11 without covering the ball padsl16. The central region 125 is aligned to the opening 113. Thus a cavity is formed from the opening 113 and the dummy die 12 to accommodate an integrated circuit chip 30. The dummy die 12 may also be utilized to avoid contaminating the ball pads 116 during the formation of the package body 50. Further, the thickness of the dummy die 12 is smaller than the diameter of solder balls 50. Usually the dummy die 12 can be a bare silicon chip without any active electrical elements or a discarded chip (also call an ink die). In this embodiment, the dummy die 12 does not have electrically connection with the wiring board 11. Preferably, a metal film 121 of copper or gold is formed on the exposed second surface 124 of the dummy die 12 by sputtering technique to improve thermal dissipation.

The integrated circuit chip 30 has an active surface 31 and a back surface 32 corresponding to the active surface 31. A plurality of bonding pads 33 are formed on the active surface 31. The integrated circuit chip 30 is disposed inside the cavity of the composite substrate 10. The back surface 32 of the integrated circuit chip 30 is attached to the central region 125 of the dummy die 12 by adhesive 34 or tape. Because both the integrated circuit chip 30 and the dummy die 12 have the same coefficient of thermal expansion, there is no residual thermal stress at the interface between the integrated circuit chip 30 and the dummy die 12, which is much better than conventional BGA package which a chip is directly attached to the cavity of a substrate. A plurality of bonding wires 20 electrically connect the bonding pads 33 of the integrated circuit chip 30 with the corresponding connecting pads 115 of the wiring board 11. The connecting pads 115 are formed at the step 114 so that the loop height of the bonding wires 20 are greatly reduced, preferably is lower than the upper surface 111 of the wiring board 11.

The package body 40 is formed in the chip cavity of the composite substrate 10 to seal the chip 30 and the bonding wires 20, which is located in the opening 113 of the wiring board 11. Preferably the package body 40 is a dispensing material. Since the dummy die 12 covers the lower end of the opening 113 at the lower surface 112, the ball pads 116 can be not contaminated even without using special tape or molding tool during forming the package body 40. Preferably, a thermosetting liquid compound is filled into the opening 113 by dispensing then cured to form the package body 40, and the entire thin type BGA package 1 can be as thin as possible. The solder balls 50 are mounted on the ball pads 116 of the wiring board 11. In general, the solder balls 50 are lead-tin alloy.

Therefore, the present invention mentioned above is to provide a thinner BGA package. The dummy die 12 is able to protect the back surface 32 of the integrated circuit chip 30, and to form the package body 40 without contaminating the ball pads 116 of the wiring board 11. Moreover, the dummy die 12 may greatly increase the thermal dissipating surface of the integrated circuit chip 30 for enhancing thermal dissipation of the thin type BGA package 1.

A manufacturing method of the thin type BGA package 1 of the present invention will be described as follows. At first referring to FIG. 2A, a wiring board 11 is provided. During the assembly processes, a plurality of the wiring boards 11 are formed on a large strip or matrix of a printed circuit board. Each wiring board 11 has the upper surface 111, the lower surface 112 and the opening 113. The step114 is formed in the opening 113, and has a plurality of connecting pads 115. As shown in FIG. 2B, a plurality of dummy dies 12 that are aligned with each opening 113 respectively and are attached to the lower surface 112 of the wiring board 11 by thermosetting compound 122 without covering the ball pads 116. A composite substrate 10 with a chip cavity for thin type BGA is formed. It is better that a metal film 121 is formed on the exposed second surface 124 of each dummy die 12 by sputtering method. Referring to FIG. 2C, a plurality of integrated circuit chips 30 are attached to the dummy dies 12. The back surface 32 is bonded with the central region 125 of the first surface 123 of the dummy die 12 by adhesive 34. Then a plurality of bonding wires 20 electrically connect the bonding pads 33 of the integrated circuit chips 30 with the connecting pads 115 of the wiring boards 11. Referring to FIG. 2D, a package body 40 is formed in the chip cavity that is defined by the opening 113 and the dummy die 12, by liquid dispensing and curing processes. Finally, a plurality of solder balls 50 are mounted on the ball pads 116 on the lower surface 112 of the wiring board 11 to manufacture the thin type BGA package.

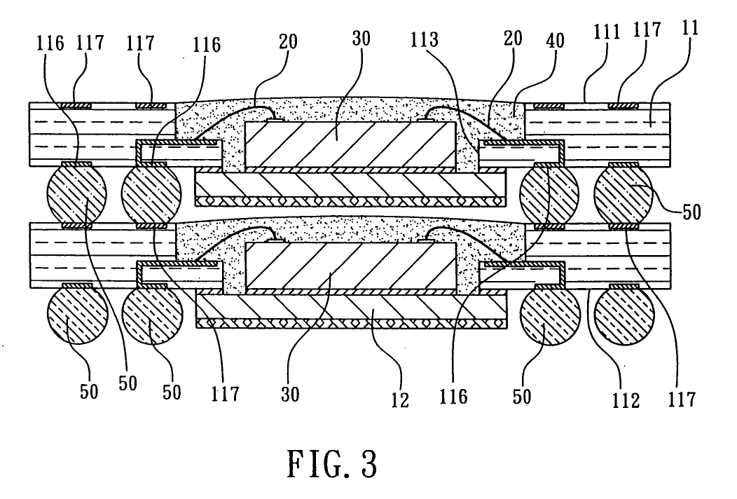

Referring to FIG. 3, another thin type BGA package is disclosed according to a second embodiment of the present invention. The thin type BGA package mainly comprises a wiring board 11, a dummy die 12, bonding wires 20, an integrated circuit chip 30, a package body 40 and solder balls 50, that as same as those of thin type BGA package 1 will be indicated by the same figure number. The integrated circuit chip 30 is disposed in the chip cavity that is defined by the opening 113 of the wiring board 11 and the dummy die 12, and is sealed by the package body 40. A plurality of ball pads 116 are formed on the lower surface 112 of the wiring board 11 for placing solder balls 50. A plurality of ball-stacking pads 117 are formed on the upper surface 1 11 of the wiring board 11 and are electrically connected with the corresponding ball pads 116. Solder balls 50 of an upper thin type BGA package are bonded to the ball-stacking pads 117 of the lower thin type BGA package, so that a plurality of thin type BGA packages can be stacked vertically. The thin type BGA package has a flat top surface with a smaller total package height so that more thin type BGA packages can be stacked together in a limited space without damaging the chips in the thin type BGA package.

The above description of embodiments of this invention is intended to be illustrated and not limiting. Other embodiments of this invention will be obvious to those skilled in the art in view of the above disclosure.

What is claimed is:

1. A thin type BGA semiconductor package comprising:
a composite substrate including a wiring board and a dummy die, wherein the wiring board has an upper surface, a lower surface and an opening, the opening passes through the upper surface and the lower surface, a step is formed in the opening, a plurality of ball pads are formed on the lower surface, a plurality of connecting pads are formed on the step and electrically connect with the ball pads, the dummy die is attached to the lower surface of the wiring board and covers the opening to form a chip cavity;
an integrated circuit chip disposed in the chip cavity, the chip having an active surface and a back surface, a plurality of bonding pads being formed on the active surface and electrically connected to the connecting pads of the wiring board, the back surface of the chip being attached to the dummy die;
a package body formed in the chip cavity of the composite substrate; and
a plurality of solder balls on the ball pads.

2. The package of claim 1, wherein the dummy die has a thickness smaller than the diameter of the solder balls.

3. The package of claim 1, wherein the dummy die has an exposed surface without attaching the wiring board, a metal film is formed on the exposed surface.

4. The package of claim 1, wherein the wiring board has a plurality of ball-stacking pads formed on the upper surface of the wiring board.

5. A thin type semiconductor package comprising:
a composite substrate including a wiring board and a dummy die, wherein the wiring board has an upper surface, a lower surface and an opening, the opening passes through the upper surface and the lower surface, a plurality of ball pads are formed on the lower surface, a plurality of connecting pads are formed around the opening and electrically connect with the ball pads, the dummy die is attached to the lower surface of the wiring board and covers the opening to form a chip cavity;
an integrated circuit chip disposed in the chip cavity, the chip having an active surface and a back surface, a plurality of bonding pads being formed on the active surface and electrically connected to the connecting pads of the wiring board, the back surface of the chip being attached to the dummy die; and
a package body formed in the chip cavity of the composite substrate.

6. The package of claim 5, wherein the dummy die has an exposed surface without attaching the wiring board, a metal film is formed on the exposed surface.

7. The package of claim 5, further comprising a thermosetting compound mechanically bonding the dummy die and the wiring board.

8. A thin type semiconductor package comprising:
a composite substrate including a wiring board and a dummy die, wherein the wiring board has an upper surface, a lower surface and an opening, the opening passes through the upper surface and the lower surface, a plurality of ball pads are formed on the lower surface, a plurality of connecting pads are formed around the opening and electrically connect with the ball pads, the dummy die has a first surface and a second surface, the first surface of the dummy die includes a central region and a peripheral region surrounding the central region, the peripheral region of the dummy die is attached to the lower surface of the wiring board;
an integrated circuit chip having an active surface and a back surface, a plurality of bonding pads being formed on the active surface, the back surface being attached to the central region of the dummy die;
a plurality of bonding wires connecting the bonding pads of the chip with the connecting pads of the wiring board; and
a package body formed in the opening of the wiring board and sealing the chip and the bonding wires.

9. The package of claim 8, wherein the package body is a dispensing material.

10. The package of claim 8, wherein the dummy die has a thickness smaller than the diameter of the solder balls.

11. The package of claim 8, wherein the dummy die has a metal film being formed on the second surface thereof.

12. The package of claim 8, wherein the wiring board has a plurality of ball-stacking pads on the upper surface of the wiring board.
